(19) United States
(12) Patent Application Publication
(10) Pub. No.: US 2023/0238392 A1
(43) Pub. Date: Jul. 27, 2023

(54) ARRAY SUBSTRATE AND DISPLAY PANEL

(71) Applicants: Mianyang HKC Optoelectronics Technology Co., Ltd., Mianyang (CN); HKC Corporation Limited, Shenzhen (CN)

(72) Inventors: Guoduo CHEN, Mianyang (CN); Rongrong LI, Mianyang (CN)

(73) Assignees: Mianyang HKC Optoelectronics Technology Co., Ltd., Mianyang, Sichuan (CN); HKC Corporation Limited, Shenzhen (CN)

(21) Appl. No.: 18/089,740

(22) Filed: Dec. 28, 2022

(30) Foreign Application Priority Data
Jan. 26, 2022 (CN) 202210095166.0

(51) Int. Cl. H01L 27/12; G02F 1/1362

(52) U.S. Cl. CPC H01L 27/124; G02F 1/136286

(57) ABSTRACT

An array substrate and a display panel are provided. The array substrate includes a bonding area and a fanout area connected with the bonding area. The fanout area includes a straight-line area and a slant-line area. The straight-line area is connected between the slant-line area and bonding area. The first wire in the straight-line area is connected with the bonding lead in the bonding area. The second wire in the slant-line area is connected with the first wire. A width of a first preset length of the first wire adjacent to the bonding area is equal to a width of the bonding lead. Alternatively, a width of a second preset length of the first wire adjacent to bonding area is not smaller than a width of the second wire and not larger than a width of the bonding lead.

### CROSS-REFERENCE TO RELATED APPLICATIONS

This application claims priority under 35 U.S.C. § 119(a) to Chinese Patent Application No. 202210095166.0, filed Jan. 26, 2022, the entire disclosure of which is incorporated herein by reference.

### TECHNICAL FIELD

The disclosure relates to the field of display technology, and in particular to an array substrate and a display panel including the array substrate.

### BACKGROUND

Thin Film Transistor-Liquid Crystal Display (TFT-LCD) has many advantages such as thin body, power saving, and no radiation. Therefore, TFT-LCD has been widely used in LCD TV, mobile phone, Personal Digital Assistant (PDA), digital camera, computer screen, projector or notebook computer screen, and other electronic devices, and plays a dominant role in the field of display. Therefore, among current LCD technologies with rapid development, TFT-LCD has been widely favored by people.

Generally, TFT-LCD includes a display panel and a backlight module. The display panel generally has a display area, as well as a bonding area and a fanout area disposed around the display area. The display area and the bonding area are connected by the fanout area to realize data signal transmission. However, in a design of wires in the fanout area of a CF on Array (COA)-based product, as a width of a bonding lead in the bonding area is larger than a width of a wire in the fanout area, a width difference at the junction of the bonding area and the fanout area is too large, such that an undercut is prone to be formed at the junction of the bonding area and the fanout area in a manufacturing process, resulting in poor wire-quality caused by water vapor infiltration.

### SUMMARY

In a first aspect, an array substrate is provided in the present disclosure. The array substrate includes a bonding area and a fanout area connected with the bonding area. The fanout area includes a straight-line area and a slant-line area. The straight-line area is connected between the slant-line area and the bonding area. The bonding area includes multiple bonding leads. The straight-line area includes multiple first wires. The slant-line area includes multiple second wires. The first wire is electrically connected with the bonding lead, and the second wire is electrically connected with the first wire. Within the straight-line area, a width of a first preset length of a first wire adjacent to the bonding area is equal to a width of the bonding lead, and the first preset length satisfies: a predetermined designed width of the first wire at an end adjacent to the bonding area is larger than a minimum ratio of a width of the second wire to a spacing between two adjacent second wires, or within the straight-line area, a width of a second preset length of the first wire adjacent to the bonding area is not smaller than a width of the second wire and not larger than a width of each of the multiple bonding leads, and a width of the second preset length of the first wire at an end near the bonding area is larger than a width of the first wire at an end away from the bonding area, and the second preset length satisfies: a predetermined designed width of the first wire at an end adjacent to the bonding area is larger than a minimum ratio of a width of the second wire to a spacing between two adjacent second wires.

In a second aspect, a display panel is provided in the present disclosure. The display panel includes the array substrate of the first aspect, a color film substrate, and a liquid crystal layer between the array substrate and the color film substrate.

### BRIEF DESCRIPTION OF THE DRAWINGS

FIG. 1 is a schematic overall structural diagram of an array substrate disclosed in implementations of the present disclosure.

FIG. 2 is a schematic cross-sectional structural diagram of a bonding area and a fanout area of the array substrate disclosed in implementations of the present disclosure.

FIG. 3 is a schematic partial cross-sectional diagram of a bonding area and a straight-line area of the array substrate disclosed in implementations of the present disclosure.

FIG. 4 is a schematic partial cross-sectional diagram of a bonding area and a straight-line area of the array substrate disclosed in implementations of the present disclosure.

FIG. 5 is a schematic partial cross-sectional diagram of a fanout area of the array substrate disclosed in implementations of the present disclosure.

FIG. 6 is a schematic structural diagram of layers of the array substrate along a direction from II to III in FIG. 2 disclosed in implementations of the present disclosure.

FIG. 7 is a schematic structural diagram of layers of the array substrate along a direction from II to III in FIG. 2 disclosed in implementations of the present disclosure.

FIG. 8 is a schematic structural diagram of layers of the array substrate along a direction from II to III in FIG. 2 disclosed in implementations of the present disclosure.

### DESCRIPTION OF REFERENCE NUMBERS:

100—array substrate, 10—connecting area, 20—bonding area, 30—fanout area, 32—straight-line area, 322—first wire, 34—slant—line area, 342—second wire, s—first boundary, m—second boundary, a—first straight-line, b—second straight-line, 51—conductive film, 52—organic layer, 53—protective layer, 54—insulating layer, 56—metal wiring layer, 561—first wiring part, 563—second wiring part, 565—third wiring part, 567—vias, 568—bonding lead, 58—substrate, 200—array substrate, 57—metal wiring layer, 571—first wiring part, 573—second wiring part, 575—third wiring part, 577—vias, 300—array substrate, 541—first insulating part, 543—second insulating part, 57a—second metal wiring layer, 56a—first metal wiring layer, 572—first vias, 574—second vias.

### DETAILED DESCRIPTION

In order to facilitate understanding of the present disclosure, a comprehensive description will be given below with reference to relevant accompanying drawings. The accompanying drawings illustrate some exemplary implementations of the present disclosure. However, the present disclosure can be implemented in many different forms and is not limited to implementations described herein. On the contrary, these implementations are provided for a more thorough and comprehensive understanding of the present disclosure.

The following implementations are described with reference to accompanying drawings to illustrate particular implementations in which the present disclosure may be implemented. The serial numbers per se assigned herein for the components, such as “first”, “second”, etc., are only used to distinguish between objects described and do not have any sequential or technical meaning. The “connection” and “coupling” in the present disclosure, unless otherwise specified, include direct and indirect connection (coupling). Direction terms mentioned in the present disclosure, such as “up”, “down”, “front”, “back”, “left”, “right”, “inside”, “outside”, “side”, etc., are only directions with reference to the directions of the accompanying drawings. Therefore, the direction terms are used for better and clearer illustration and understanding of the present disclosure, and are not intended to indicate or imply that the device or component must have a specific orientation, be constructed and operated in the particular orientation, and therefore cannot be construed as limiting to the present disclosure.

In the description of the present disclosure, it should be noted that unless otherwise expressly specified or defined, terms such as “mount”, “couple”, and “connect” should be understood broadly. For example, the connection may be a fixed connection, or a detachable connection, or an integrated connection; may be a mechanical connection; and may be a direct connection, or an indirect connection via an intermediate medium, or may be an internal communication between two components. The specific meanings of the above-mentioned terms in the present disclosure could be understood by those of ordinary skill in the art according to specific situations. It should be noted that the terms “first”, “second”, etc. in the specification, claims and accompanying drawings of the present disclosure are used to distinguish different objects, rather than to describe a specific order.

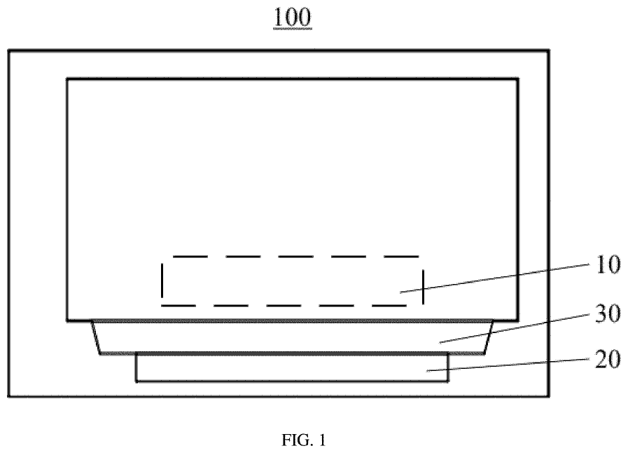

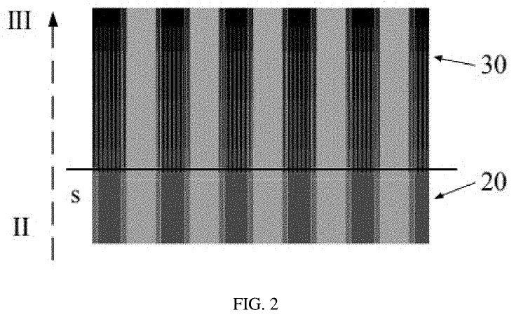

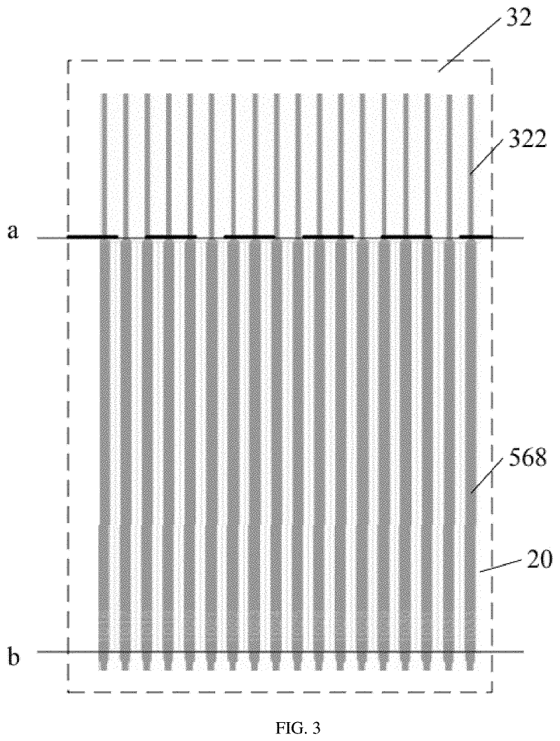

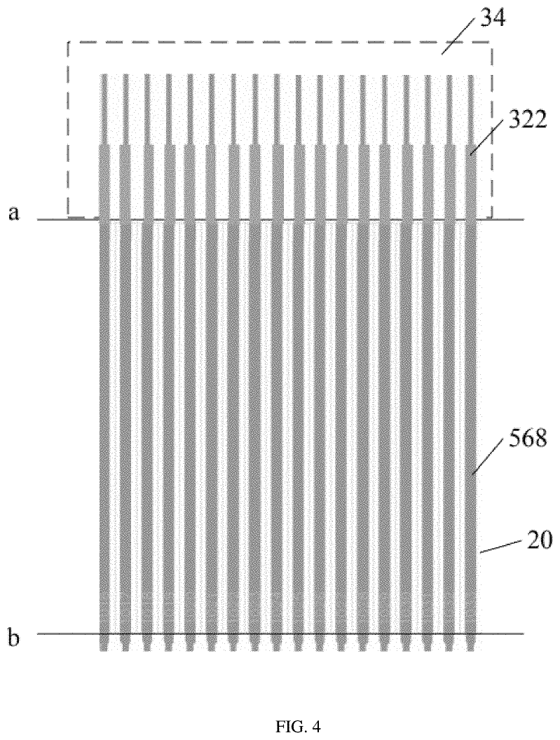

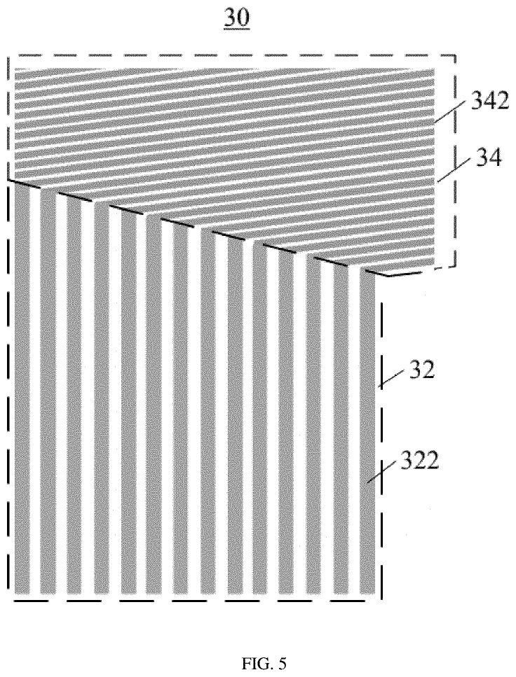

An array substrate 100 is provided in implementations of the present disclosure. Referring to FIG. 1, FIG. 2, FIG. 3, FIG. 4, and FIG. 5, FIG. 1 is a schematic overall structural diagram of an array substrate disclosed in implementations of the present disclosure, FIG. 2 is a schematic cross-sectional structural diagram of a bonding area and a fanout area of the array substrate disclosed in implementations of the present disclosure, FIG. 3 is a schematic partial cross-sectional diagram of the bonding area and a straight-line area of the array substrate disclosed in implementations of the present disclosure, FIG. 4 is a schematic partial cross-sectional diagram of the bonding area and the straight-line area of the array substrate disclosed in implementations of the present disclosure, and FIG. 5 is a schematic partial cross-sectional diagram of the fanout area of the array substrate disclosed in implementations of the present disclosure.

As illustrated in FIG. 1 and FIG. 2, in the array substrate 100 provided in implementations of the present disclosure, the array substrate 100 may include at least a bonding area 20 and a fanout area 30. The bonding area 20 is electrically connected with the fanout area 30. As illustrated in FIG. 3 and FIG. 5, the bonding area 20 includes multiple bonding leads 568. The fanout area 30 includes a straight-line area 32 and a slant-line area 34. The slant-line area 34 is adjacent to a side of the straight-line area 32, and an opposite side of the straight-line area 32 is adjacent to the bonding area 20, that is, the straight-line area 32 is connected between the slant-line area 34 and the bonding area 20. The straight-line area 32 includes multiple first wires 322. The slant-line area 34 includes multiple second wires 342. The first wires 322 are electrically connected with the bonding leads 568 in one-to-one correspondence, and the second wires 342 are electrically connected with the first wires 322 in one-to-one correspondence. Within the straight-line area 32, a width of a first preset length of each of the multiple first wires 322 adjacent to the bonding area 20 is equal to a width of each of the multiple bonding leads 568. That is, for the first preset length of the first wire 322 adjacent to the bonding area 20, the width of the first wire 322 is equal to the width of the corresponding bonding lead 568.

Alternatively, within the straight-line area 32, a width of a second preset length of the first wire 322 adjacent to the bonding area 20 is not smaller than a width of the second wire 342 and not larger than a width of each of the multiple bonding leads 568, and meanwhile, within the straight-line area 32, a width of the second preset length of the first wire 322 adjacent to the bonding area 20 at an end near the bonding area 20 is larger than a width of the first wire 322 at an end away from the bonding area 20. That is, for the second preset length of the first wire 322 adjacent to the bonding area 20, the width of the first wire 322 is not smaller than the width of the corresponding second wire 342 and not larger than the width of the corresponding bonding lead 568, and meanwhile, for the second preset length of the first wire 322 adjacent to the bonding area, the width of the first wire 322 at an end near the bonding area 20 is larger than the width of the first wire 322 at an end away from the bonding area 20. That is, the straight-line area 32 is connected between the slant-line area 34 and the bonding area 20, the first wire 322 in the straight-line area 32 has an end near to the bonding area 20, and has an opposite end away from the bonding area 20. The second preset length of the first wire 322 has a width at the end near the bonding area 20 larger than a width at the end away from the bonding area 20. In this way, a smooth transition between the width of the first wire 322 in the straight-line area 32 and the width of the bonding lead 568 in the bonding area 20 can be realized, thereby improving the yield of the wires of the array substrate 100.

In implementations of the present disclosure, within the straight-line area 32, a width of the second preset length of each of the multiple first wires 322 adjacent to the bonding area 20 may change gradually. That is, a width of the second preset length of each of the multiple first wires is gradually reduced in the direction from near to far relative to the bonding area. For example, the width of the second preset length of each of the multiple first wires 322 may change regularly, and the change may be shown as e.g., smooth curves or multiple uniformly-reduced polyline-segments (i.e., the axial cross section of the first wire 322 in the preset length may be multiple stacked isosceles trapezoids or trapezoids).

In implementations of the present disclosure, the bonding area 20 is adjacent and electrically connected to the fanout area 30. The multiple bonding leads 568 in the bonding area 20 may be disposed in parallel and at intervals. The straight-line area 32 is adjacent and electrically connected to the bonding area 20. The multiple first wires 322 in the straight-line area 32 may be disposed in parallel and at intervals, and each of the multiple first wires 322 is electrically connected with a corresponding bonding lead 568. The slant-line area 34 is adjacent and electrically connected to the straight-line area 32. The multiple second wires 342 in the slant-line area 34 may be disposed in parallel and at intervals, and each of the multiple second wires 342 is electrically connected with a corresponding first wire 322. That is, the first wire 322 is connected between the bonding lead 568 and the second wire 342.

In summary, the bonding area 20 is electrically connected with the fanout area 30. The bonding area 20 includes the bonding leads 568. The fanout area 30 includes the straight-line area 32 and the slant-line area 34. Within the straight-line area 32, a width of a preset length of a wire adjacent to the bonding area 20 at an end near the bonding area 20 is equal to a width of the bonding lead 568. Alternatively, a width of a second preset length of each of the multiple first wires 322 is not smaller than a width of each of the multiple second wires 342 and not larger than a width of each of the multiple bonding leads 568, and meanwhile, a width of the second preset length of each of the multiple first wires 322 at an end near the bonding area 20 is larger than a width of each of the multiple first wires 322 at an end away from the bonding area 20. In this way, a smooth transition between the width of the first wire 322 in the straight-line area 32 and the width of the bonding lead 568 in the bonding area 20 can be realized, thereby avoiding the problem of water vapor infiltration due to a large width difference at the junction of the straight-line area and the bonding area, since the large width difference may cause an undercut prone to be formed at a junction of the bonding area and the fanout area in the manufacturing process, such as etching process. Therefore, the yield of the wires of the array substrate can be improved, which can effectively improve the performance of the array substrate 100.

Still referring to FIG. 1, the array substrate 100 also includes a connecting area 10, an Active Area (AA), and a peripheral functional area. The connecting area 10 is disposed in the AA. The bonding area 20 and the fanout area 30 are disposed in the peripheral functional area. The fanout area 30 is disposed adjacent to the AA and electrically connected with the connecting area 10. The connecting area 10 may receive an electrical signal from the fanout area 30. The bonding area 20 is disposed adjacent to the fanout area 30 and may transmit an electrical signal to the fanout area 30.

In an implementation of the present disclosure, the fanout area 30 also includes a data signal line (not shown) connecting the AA. The AA is a part mainly configured for displaying images. A drive Integrated Circuit (IC) may be disposed in the bonding area 20 which connects the drive IC to the panel. Multiple wires can be disposed in the fanout area 30 and distributed in a fan shape to connect the wires in the AA with a driving circuit in the peripheral functional area.

Still referring to FIG. 2, the first boundary s in FIG. 2 shows a plane which is a junction between the bonding area 20 and the fanout area 30. Specifically, in FIG. 2, the fanout area 30 of the array substrate 100 is at one side of the first boundary s (the upper side of the first boundary s in FIG. 2) is, and the bonding area 20 of the array substrate 100 is at the other side of the first boundary s (the lower side of the first boundary s in FIG. 2).

It should be noted that, in existing products, the wires used for connecting the bonding area 20 and the fanout area 30 generally have a large width difference at the junction of the bonding area 20 and the fanout area 30, such that a reverse chamfering or an undercut are prone to be formed in the manufacturing process, resulting in water vapor infiltration and thus poor wire-quality, thereby affecting the yield of wire-connection and further the reliability of signal transmission of the array substrate 100.

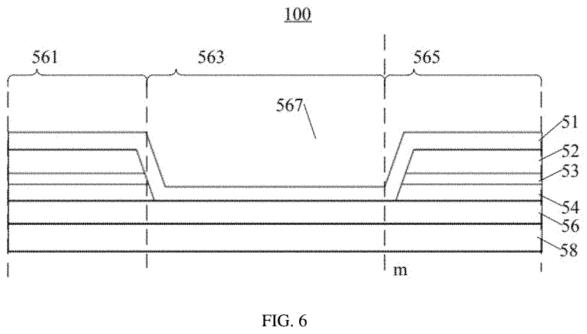

Referring also to FIG. 6 to FIG. 8, the second boundary m in FIG. 6 to FIG. 8 shows a plane which is a junction between the bonding area 20 and the fanout area 30. Specifically, in FIG. 6 to FIG. 8, the bonding area 20 of the array substrate 100 is at the left side of the second boundary m, and the fanout area 30 of the array substrate 100 is at the right part of the second boundary m. As can be seen in conjunction with FIG. 2, the first boundary s is coplanar with the second boundary m.

Referring to FIG. 3, FIG. 4, and FIG. 6, FIG. 6 is a schematic structural diagram of layers of the array substrate along a direction from II to III in FIG. 2 disclosed in implementations of the present disclosure. In implementations of the present disclosure, the array substrate 100 may include an organic layer 52, a protective layer 53, an insulating layer (such as a Gate Insulator (GI)) 54, a metal wiring layer 56, and a substrate 58 stacked from top to bottom. The substrate 58 is disposed at the lowest layer of the array substrate 100. Specifically, the substrate 58 is disposed at the lowest layer of layers of the array substrate 100 for supporting other layers of the array substrate 100 disposed on the substrate 58.

The metal wiring layer 56 is disposed on the substrate 58. The metal wiring layer 56 includes the bonding lead 568, the first wire 322, and the second wire 342. The first wire 322 is connected between the bonding lead 568 and the second wire 342.

The insulating layer 54 is disposed on the metal wiring layer 56. The insulating layer 54 may be made of an inorganic material such as silicon nitride or silicon oxide.

The protective layer 53 is disposed on the insulating layer 54 for protecting the array substrate 100 including the protective layer 53 from damage.

The organic layer 52 is disposed on the protective layer 53. The organic layer 52 may be made of soluble polyfluoroalkoxy (also known as Teflon PFA, PFA).

In an implementation, the metal wiring layer 56 includes a first wiring part 561, a second wiring part 563, and a third wiring part 565 connected in sequence. An area corresponding to the second wiring part 563 of the metal wiring layer 56 includes the bonding lead 568. An area corresponding to the third wiring part 565 of the metal wiring layer 56 includes the first wire 322. The array substrate 100 defines at least a vias 567. The vias 567 penetrates the organic layer 52, the protective layer 53, and the insulating layer 54 sequentially to expose the second wiring part 563 of the metal wiring layer 56. That is, the vias 567 penetrates the organic layer 52, the protective layer 53, and the insulating layer 54 sequentially until the second wiring part 563 of the metal wiring layer 56 is exposed, i.e., the vias 567 forms a groove structure in the array substrate 100, with the second wiring part 563 of the metal wiring layer 56 as a bottom wall of the groove structure.

In implementations of the present disclosure, the array substrate 100 also includes a conductive film 51. The conductive film 51 may be made of Indium Tin Oxide (ITO). The conductive film 51 covers a sidewall of the vias 567 and the second wiring part 563 of the metal wiring layer 56 at the bottom of the vias 567. The conductive film 51 also covers a surface area of the organic layer 52 away from the protective layer 53. That is, the conductive film 51 serves as an upper surface of the array substrate 100. Since the vias 567 penetrates the organic layer 52, the protective layer 53, and the insulating layer 54 sequentially to expose the second wiring part 563, and the conductive film 51 covers the second wiring part 563, the conductive film 51 is connected with the second wiring part 563 of the metal wiring layer 56 in the vias 567.

In implementations of the present disclosure, the bonding lead 568 is used for electrically connecting the second wiring part 563 of the metal wiring layer 56 and the conductive film 51. That is, the conductive film 51 is connected with the second wiring part 563 of the metal wiring layer 56 in the vias 567 through the bonding lead 568.

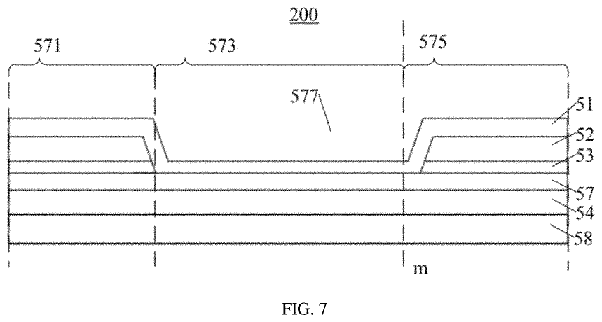

Referring to FIG. 3, FIG. 4, and FIG. 7, FIG. 7 is a schematic structural diagram of layers of the array substrate along a direction from II to III in FIG. 2 disclosed in implementations of the present disclosure.

In implementations of the present disclosure, the array substrate 200 may include an organic layer 52, a protective layer 53, a metal wiring layer 57, an insulating layer 54, and a substrate 58 stacked from top to bottom. The substrate 58 is disposed at the lowest layer of the layer structure of the array substrate 100. Specifically, the substrate 58 is disposed at the lowest layer of the array substrate 100 for supporting other layers of the array substrate 100 disposed on the substrate 58.

The insulating layer 54 is disposed on the substrate 58. The insulating layer 54 may be made of an inorganic material such as silicon nitride or silicon oxide.

The metal wiring layer 57 is disposed on the insulating layer 54. The metal wiring layer 57 includes the bonding lead 568, the first wire 322, and the second wire 342. The first wire 322 is connected between the bonding lead 568 and the second wire 342.

The protective layer 53 is disposed on the metal wiring layer 57 for protecting the array substrate including the protective layer 53 from damage.

The organic layer 52 is disposed on the protective layer 53. The organic layer 52 may be made of soluble polyfluoroalkoxy.

In an implementation, the metal wiring layer 57 includes a first wiring part 571, a second wiring part 573, and a third wiring part 575 connected sequentially. An area corresponding to the second wiring part 573 of the metal wiring layer 57 includes the bonding lead 568. An area corresponding to the third wiring part 575 of the metal wiring layer 57 includes the first wire 322. The array substrate 200 defines at least a vias 577. The vias 577 penetrates the organic layer 52 and the protective layer 53 sequentially to expose the second wiring part 573 of the metal wiring layer 57. That is, the vias 577 penetrates the organic layer 52 and the protective layer 53 sequentially until the second wiring part 573 of the metal wiring layer 57 is exposed, i.e., the vias 577 forms a groove structure in the array substrate 100, with a partial area of the second wiring part 573 of the metal wiring layer 57 as a bottom wall of the groove structure.

In implementations of the present disclosure, the array substrate 200 also includes a conductive film 51. The conductive film 51 may be made of ITO. The conductive film 51 covers a sidewall of the vias 577 and the second wiring part 573 of the metal wiring layer 57 at a bottom of the vias 577. The conductive film 51 also covers a surface area of the organic layer 52 away from the protective layer 53. That is, the conductive film 51 serves as an upper surface of the array substrate 200. Since the vias 577 penetrates the organic layer 52 and the protective layer 53 sequentially to expose the second wiring part 573, and the conductive film 51 covers the second wiring part 573, the conductive film 51 is connected with the second wiring part 573 of the metal wiring layer 57 in the vias 577.

In implementations of the present disclosure, the bonding lead 568 is used for connecting the second wiring part 573 of the metal wiring layer 57 and the conductive film 51. That is, the conductive film 51 is connected with the second wiring part 573 of the metal wiring layer 57 in the vias 577 through the bonding lead 568.

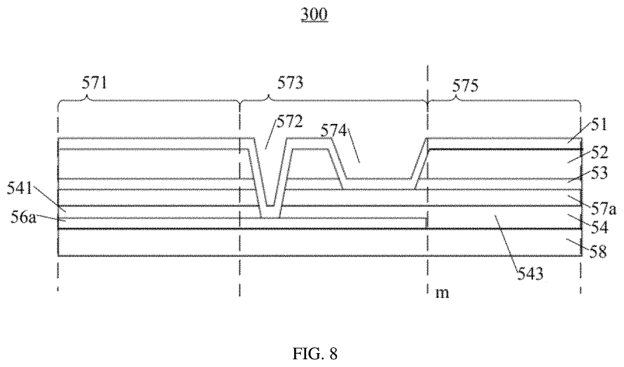

Referring to FIG. 3, FIG. 4, and FIG. 8, FIG. 8 is a schematic structural diagram of layers of the bonding area and the straight-line area layer of the array substrate disclosed in implementations of the present disclosure.

In implementations of the present disclosure, the array substrate 300 may include an organic layer 52, a protective layer 53, a second metal wiring layer 57a, an insulating layer 54, a first metal wiring layer 56a, and a substrate 58. The substrate 58 is disposed at the lowest layer of the array substrate 100.

In implementations of the present disclosure, the first metal wiring layer 56a may be made of the same material as the metal wiring layer 56 in the array substrate 100 according to the implementations, and the second metal wiring layer 57a may be made of the same material as the metal wiring layer 57 in the array substrate 200 according to the implementations, which are not specifically limited in the present disclosure.

Specifically, the substrate 58 is disposed at the lowest layer of the array substrate 100 for supporting other layers of the array substrate 100 disposed on the substrate 58.

The first metal wiring layer 56a is disposed on the substrate 58 at a position corresponding to the bonding area 20. That is, a length of an orthographic projection of the first metal wiring layer 56a on the substrate 58 is equal to a length of the bonding area 20 (i.e., the left side of the first boundary m in the array substrate 100). A side of the first metal wiring layer 56a is aligned with a side of the substrate 58 in the bonding area 20. The first metal wiring layer 56a includes a part of the bonding leads 568.

The insulating layer 54 is disposed on the first metal wiring layer 56a and the substrate 58. The insulating layer 54 may be made of an inorganic material such as silicon nitride or silicon oxide. Specifically, the insulating layer 54 as a whole may have an “L” shape. The insulating layer 54 may include a first insulating part 541 and a second insulating part 543 connected together. The first insulating part 541 is disposed on the first metal wiring layer 56a at a position corresponding to the bonding area 20. That is, an orthographic projection of the first insulating part 541 on the substrate 58 overlaps with an orthographic projection of the first metal wiring layer 56a on the substrate 58. The second insulating part 543 is disposed on the substrate 58 at a position corresponding to the fanout area 30. An upper surface of the second insulating part 543 is flush with an upper surface of the first insulating part 541. That is, the first insulating part 541 of the insulating layer 54 is disposed on the first metal wiring layer 56a at a position corresponding to the bonding area 20. The second insulating part 543 is disposed on the substrate 58 at a position corresponding to the fanout area 30. The first insulating part 541 is thinner than the second insulating part 543.

The second metal wiring layer 57a is disposed on the insulating layer 54. That is, the first insulating part 541 corresponds to the bonding area 20, and is disposed between the first metal wiring layer 56a and the second metal wiring layer 57a. The second insulating part 543 corresponds to the fanout area 30, and is disposed between the substrate 58 and the second metal wiring layer 57a. The second metal wiring layer 57a includes another part of the bonding lead 568, the first wire 322, and the second wire 342. That is, the bonding lead 568 is in the first metal wiring layer 56a and the second metal wiring layer 57a, respectively, i.e., a part of the bonding leads 568 are in the first metal wiring layer 56a and another part of the bonding leads 568 are in the second metal wiring layer 57a.

The protective layer 53 is disposed on the second metal wiring layer 57a for protecting the array substrate including the protective layer 53 from damage.

The organic layer 52 is disposed on the protective layer 53. The organic layer 52 may be made of soluble polyfluoroalkoxy.

In an implementation, the second metal wiring layer 57a includes a first wiring part 571, a second wiring part 573, and a third wiring part 575 connected sequentially. An area corresponding to the second wiring part 573 of the second metal wiring layer 57a includes the bonding leads 568. An area corresponding to the third wiring part 575 of the second metal wiring layer 57a includes the first wires 322. The array substrate 300 defines at least a first vias 572. The first vias 572 penetrates the organic layer 52, the protective layer 53, the second metal wiring layer 57a, and the first insulating part 541 of the insulating layer 54 sequentially to expose the first metal wiring layer 56a. That is, the first vias 572 penetrates the organic layer 52, the protective layer 53, the second metal wiring layer 57a, and the first insulating part 541 of the insulating layer 54 until the first metal wiring layer 56a is exposed, i.e., the first vias 572 forms a groove structure in the array substrate 300, with an area of the first metal wiring layer 56a corresponding to the first vias 572 as a bottom wall of the groove structure.

The array substrate 300 defines at least a second vias 574. The vias 574 penetrates the organic layer 52 and the protective layer 53 sequentially to expose the second wiring part 573 of the second metal wiring layer 57a. That is, the second vias 574 penetrates the organic layer 52 and the protective layer 53 sequentially until the second wiring part 573 of the second metal wiring layer 57a is exposed, i.e., the second vias 574 forms a groove structure in the array substrate 300, with an area of the second wiring part 573 of the second metal wiring layer 57a corresponding to the second vias 574 as a bottom wall of the groove structure.

In implementations of the present disclosure, the array substrate 300 also includes a conductive film 51. The conductive film 51 may be made of ITO. The conductive film 51 covers a sidewall of the first vias 572 and the first metal wiring layer 56a at a bottom of the first vias 572, and a sidewall of the second vias 574 and the second metal wiring layer 57a at a bottom of the second vias 574. The conductive film 51 also covers a surface area of the organic layer 52 away from the protective layer 53 and around the first vias 572 and the second vias 574. That is, the conductive film 51 serves as an upper surface of the array substrate 200. Since the first vias 572 penetrates the organic layer 52, the protective layer 53, the second metal wiring layer 57a, and the first insulating part 541 of the insulating layer 54 sequentially until the first metal wiring layer 56a is exposed, and the second vias 574 penetrates the organic layer 52 and the protective layer 53 sequentially until the second wiring part 573 of the second metal wiring layer 57a is exposed, as well as the conductive film 51 covers a surface area of the first metal wiring layer 56a corresponding to the first vias 572 and a surface area of the second wiring part 573 corresponding to the second vias 574, the conductive film 51 is connected to the first metal wiring layer 56a in the first vias 572, and the conductive film 51 is connected to the second wiring part 573 of the second metal wiring layer 57a in the first vias 572 and the second vias 574.

In implementations of the present disclosure, the bonding lead 568 is used for electrically connecting the first metal wiring layer 56a, the second wiring part 573 of the second metal wiring layer 57a, and the conductive film 51. That is, the conductive film 51 is connected with the first metal wiring layer 56a in the first vias 572 through the bonding lead 568. The conductive film 51 is connected with the second wiring part 573 of the second metal wiring layer 57a in the first vias 572 and the second vias 574 through the bonding lead 568.

Still referring to FIG. 3, FIG. 4, and FIG. 5, FIG. 3 is a schematic partial cross-sectional diagram of the bonding area and a straight-line area of the array substrate disclosed in implementations of the present disclosure, FIG. 4 is a schematic partial cross-sectional diagram of the bonding area and the straight-line area of the array substrate disclosed in implementations of the present disclosure, and FIG. 5 is a schematic partial cross-sectional diagram of the fanout area of the array substrate disclosed in implementations of the present disclosure. As illustrated in FIG. 3 and FIG. 4, a distance between a first straight-line a and a second straight-line b is the length of each of the multiple bonding leads 568. The first straight-line a is the boundary between the bonding area 20 and the straight-line area 32. That is, the straight-line area 32 is at one side of the first straight-line a (in FIG. 3 or FIG. 4, the straight-line area 32 is at the upper side of the first straight-line a), and the bonding area 20 is at the other side of the first straight-line a (in FIG. 3 or FIG. 4, the bonding area 20 is at the lower side of the first straight-line a).

In implementations of the present disclosure, as illustrated in FIG. 5, the fanout area 30 includes the straight-line areas 32 and the bonding area 20. The straight-line areas 32 is adjacent and electrically connected to the bonding area 20. Each of the multiple first wires 322 in the straight-line area 32 is electrically connected with a corresponding bonding lead 568. The slant-line area 34 is adjacent and electrically connected to the straight-line area 32. Each of the multiple second wires 342 in the slant-line area 34 is electrically connected with corresponding first wire 322.

Still referring to FIG. 3, in implementations of the present disclosure, at a side of the straight-line area 32 adjacent to the bonding area 20, a width of a first preset length of the first wire is equal to a width of the bonding lead 568. The first preset length satisfies: a predetermined designed width of the first preset length of the first wire 322 at an end adjacent to the bonding area 20 is larger than a specific value of a ratio of “W” to “S” of the second wire 342 in the slant-line area 34, where “W” refers to a width of the second wire 342 in the slant-line area 34, and “S” refers to a spacing between two adjacent second wires 342 in the slant-line area 34.

In an implementation, the predetermined designed width refers to a width of the first wire determined before wiring optimization of the array substrate.

In an implementation, the manufacturing process of the array substrate 100 will be affected by the ratio of “W” to “S”. The specific value may be the minimum ratio of “W” to “S”, which is not specifically limited in the present disclosure.

Still referring to FIG. 4, in other implementations of the present disclosure, within the straight-line area 32, a width of a second preset length of each of the multiple first wires 322 adjacent to the bonding area 20 is not smaller than a width of each of the multiple second wires 342 and not larger than a width of each of the multiple bonding leads 568. A width of the second preset length of each of the multiple first wires 322 at an end near the bonding area 20 is larger than a width of the first wire 322 at an end away from the bonding area 20. Meanwhile, a width of the second preset length of each of the multiple first wires 322 may change gradually. That is, a width of the second preset length of each of the multiple first wires is gradually reduced in the direction from near to far relative to the bonding area. For example, the width of the second preset length of each of the multiple first wires 322 may change regularly, and the change may be shown as e.g., smooth curves or multiple uniformly-reduced polyline-segments. In this way, a smooth transition between the width of the first wire 322 in the straight-line area 32 and the width of the bonding lead 568 in the bonding area 20 can be realized, thereby improving the yield of the wires of the array substrate 100. The second preset length satisfies: a predetermined designed width of the second preset length of each of the multiple first wires 322 at an end adjacent to the bonding area 20 is larger than a specific value of a ratio of “W” to “S” in the slant-line area 34. The predetermined designed width of the second preset length of each of the multiple first wires 322 should ensure a complete layout of a Gate on Array (GOA) circuit or a drive IC in the fanout area 30.

In implementations of the present disclosure, “W” refers to the width of the second wire 342 in the slant-line area 34, and “S” refers to the spacing between two adjacent second wires 342 in the slant-line area 34.

In an implementation, the predetermined designed width refers to a width of the first wire determined before wiring optimization of the array substrate.

In an implementation, the manufacturing process of the array substrate 100 will be affected by the ratio of “W” to “S”. The specific value may be the minimum the ratio of “W” to “S” may be minimized, which is not specifically limited in the present disclosure.

Based on the same concept for the array substrate in any of the above implementations, a display panel is further provided in implementations of the present disclosure. The display panel includes the array substrate in any of the above implementations, a color film substrate, and a liquid crystal layer disposed between the array substrate and the color film substrate. Specifically, the color film substrate is disposed on the conductive film 51 at an end away from the substrate 58, and the liquid crystal layer is disposed between the array substrate and the color film substrate.

Based on the same concept, for the display panel, a display device is further provided in implementations of the present disclosure. The display device includes the display panel in the implementations and a backlight module. The display panel is disposed at the light-emitting side of the backlight module. The backlight module provides backlight for the display panel. It can be appreciated that the display device also includes other structures, and only those related to the disclosure are listed in the present disclosure. Moreover, the display device provided in the implementations of the present disclosure can be any product or component with display function, such as a notebook computer display screen, an LCD, a liquid crystal television, a digital photo frame, a mobile phone, and a tablet computer, etc.

In an implementation, the display device also includes other necessary components such as a driving board, a power supply board, a high-voltage board, a key control board, etc., which can be supplemented by those skilled in the art according to the specific type and actual function of the display device, and will not be described herein.

It can be appreciated that the display device may be applied to electronic devices, including but not limited to a tablet computer, a notebook computer, and a desktop computer, etc., for example TFT-LCD. According to the implementations of the present disclosure, the specific type of the display device is not specifically limited, which can be designed by those skilled in the art according to the specific requirements of the electronic device of the display device, and will not be described here.

It can be appreciated that the display device may also be applied to electronic devices including functions of such as a PDA and/or a music player, e.g., a mobile phone, a tablet computer, a wearable electronic device with a wireless communication function (such as a smart watch), etc. The electronic devices may also be other electronic devices such as a laptop with a touch-sensitive surface (e.g., a touch panel), etc. In some implementations, the electronic device may have a communication function, i.e. the electronic device can establish communication with a network through the 2nd Generation Cellular Communication Technical Specification (2G), the 3rd Generation Cellular Communication Technical Specification (3G), the 4th Generation Cellular Communication Technical Specification (4G), the 5th Generation Cellular Communication Technical Specification (5G), Wireless Local Area Network (W-LAN), or any communication technologies that may arise in the future. For the sake of simplicity, it is not specifically limited in the implementations of the present disclosure.

In summary, according to the array substrate 100, the display panel, and the display device of the present disclosure, the fanout area 30 is electrically connected with the connecting area 10. The bonding area 20 is electrically connected with the fanout area 30. The bonding area 20 includes the bonding lead 568. The fanout area 30 includes the straight-line area 32 and the slant-line area 34. Within the straight-line area 32, a width of a preset length of a wire adjacent to the bonding area 20 at an end near the bonding area 20 is equal to a width of the bonding lead 568, or a width of a wire of a second preset length changes regularly, and is not smaller than a width of a wire in the slant-line area 34 and not larger than a width of the bonding lead 568. A width of the wire at an end adjacent to the bonding area is larger than a width of the wire at an end away from the bonding area. In this way, a smooth transition from the width of the bonding lead 568 in the bonding area 20 to the width of the second wire in the slant-line area 34 can be realized, which avoid the problem of poor wire quality caused by water vapor infiltration due to a reverse chamfering or an undercut at the junction of the straight-line area and the bonding area, since the reverse chamfering or the undercut are prone to be formed due to a large width difference at the junction of the straight-line area and the bonding area, especially a large width difference at an edge of a vias in a wiring design of the fanout area of COA products. As such, the yield of the wires of the array substrate can be improved, so that the performance of the array substrate and the display effect and quality of the display device can be effectively improved. In addition, at present, since the width of the bonding lead in the bonding area is generally larger than a predetermined designed width of the wires in the straight-line area, in the present disclosure, the width of the first wire in the straight-line area are widened to be equal to the width of the bonding lead or larger than the predetermined designed width. In this way, a resistance of the first wire in the straight-line area can be reduced, which can improve the signal driving and transmission of the array substrate, so that the performance of the array substrate and the display effect of the display panel and the display device can be effectively improved.

All possible combinations of the respective technical features in the implementations are described. However, as long as there is no contradiction in the combinations of these technical features, it should be considered to be within the scope of the present disclosure.

The above implementations are merely illustrative of several implementations of the present disclosure which are described in detail but should not be construed as limiting the scope of the present disclosure. It should be noted that several modifications and improvements can be made by those skilled in the art without departing from the concept of the present disclosure, and these modifications and improvements all fall within the scope of the present disclosure. Therefore, the scope of the present disclosure shall be subject to the appended claims.

1. An array substrate, comprising a bonding area and a fanout area connected with the bonding area, wherein the fanout area comprises a straight-line area and a slant-line area, the straight-line area is connected between the slant-line area and the bonding area, the bonding area comprises a plurality of bonding leads, the straight-line area comprises a plurality of first wires, the slant-line area comprises a plurality of second wires, the first wire is electrically connected with the bonding lead, and the second wire is electrically connected with the first wire, wherein
within the straight-line area, a width of a first preset length of a first wire adjacent to the bonding area is equal to a width of the bonding lead, wherein the first preset length satisfies: a predetermined designed width of the first wire at an end adjacent to the bonding area is larger than a minimum ratio of a width of the second wire to a spacing between two adjacent second wires; or
within the straight-line area, a width of a second preset length of the first wire adjacent to the bonding area is not smaller than a width of the second wire and not larger than a width of each of the plurality of bonding leads, and a width of the second preset length of the first wire at an end near the bonding area is larger than a width of the first wire at an end away from the bonding area, wherein the second preset length satisfies: a predetermined designed width of the first wire at an end adjacent to the bonding area is larger than a minimum ratio of a width of the second wire to a spacing between two adjacent second wires.

2. The array substrate of claim 1, wherein the array substrate comprises an organic layer, a protective layer, an insulating layer, a metal wiring layer, and a substrate, the metal wiring layer is disposed on the substrate, the insulating layer is disposed on the metal wiring layer, the protective layer is disposed on the insulating layer, and the organic layer is disposed on the protective layer, the metal wiring layer comprises the bonding leads, the first wires, and the second wires, and the first wire is connected between the bonding lead and the second wire.

3. The array substrate of claim 2, wherein the array substrate defines a vias, the array substrate further comprises a conductive film, the metal wiring layer comprises a first wiring part, a second wiring part, and a third wiring part connected in sequence, wherein
the vias penetrates the organic layer, the protective layer, and the insulating layer sequentially to expose the second wiring part of the metal wiring layer, the conductive film covers a sidewall of the vias and the second wiring part of the metal wiring layer at a bottom of the vias, and the conductive film further covers a surface area of the organic layer away from the protective layer; and
the conductive film is electrically connected with the second wiring part of the metal wiring layer in the vias through the bonding lead.

4. The array substrate of claim 1, wherein the array substrate comprises an organic layer, a protective layer, a metal wiring layer, an insulating layer, and a substrate, the insulating layer is disposed on the substrate, the metal wiring layer is disposed on the insulating layer, the protective layer is disposed on the metal wiring layer, and the organic layer is disposed on the protective layer, the metal wiring layer comprises the bonding leads, the first wires, and the second wires, and the first wire is connected between the bonding lead and the second wire.

5. The array substrate of claim 4, wherein the array substrate defines a vias, the array substrate further comprises a conductive film, the metal wiring layer comprises a first wiring part, a second wiring part, and a third wiring part connected in sequence;
the vias penetrates the organic layer and the protective layer sequentially to expose the second wiring part of the metal wiring layer, the conductive film covers a sidewall of the vias and the second wiring part of the metal wiring layer at a bottom of the vias, and the conductive film further covers a surface area of the organic layer away from the protective layer; and
the conductive film is electrically connected with the second wiring part of the metal wiring layer in the vias through the bonding lead.

6. The array substrate of claim 1, wherein the array substrate comprises an organic layer, a protective layer, a second metal wiring layer, an insulating layer, a first metal wiring layer, and a substrate, the first metal wiring layer is disposed on the substrate at a position corresponding to the bonding area, the insulating layer comprises a first insulating part and a second insulating part connected together, the first insulating part is disposed on the first metal wiring layer at a position corresponding to the bonding area, and the second insulating part is disposed on the substrate at a position corresponding to the fanout area; the second metal wiring layer is disposed on the insulating layer, the protective layer is disposed on the second metal wiring layer, and the organic layer is disposed on the protective layer, the first metal wiring layer comprises a part of the bonding leads, and the second metal wiring layer comprises another part of the bonding leads, the first wires, and the second wires.

7. The array substrate of claim 6, wherein the array substrate defines a first vias and a second vias, the array substrate comprises a conductive film, the second metal wiring layer comprises a first wiring part, a second wiring part, and a third wiring part connected in sequence;
the first vias penetrates the organic layer, the protective layer, the second metal wiring layer, and the first insulating part of the insulating layer sequentially to expose the first metal wiring layer, and the second vias penetrates the organic layer and the protective layer sequentially to expose the second wiring part of the second metal wiring layer;
the conductive film covers a sidewall of the first vias and the first metal wiring layer at a bottom of the first vias, and a sidewall of the second vias and the second metal wiring layer at a bottom of the second vias, and the conductive film further covers a surface area of the organic layer away from the protective layer and around the first vias and the second vias; and
the conductive film is electrically connected with the first metal wiring layer in the first vias through a bonding lead, and the conductive film is electrically connected with the second wiring part of the second metal wiring layer in the first vias and the second vias through a bonding lead.

8. (canceled)

9. The array substrate of claim 1, wherein a width of the second preset length of each of the plurality of first wires is gradually reduced in a direction from near to far relative to the bonding area.

10. A display panel, comprising:
an array substrate, comprising a bonding area and a fanout area connected with the bonding area, wherein the fanout area comprises a straight-line area and a slant-line area, the straight-line area is connected between the slant-line area and the bonding area, the bonding area comprises a plurality of bonding leads, the straight-line area comprises a plurality of first wires, the slant-line area comprises a plurality of second wires, the first wires is electrically connected with the bonding lead, and the second wire is electrically connected with the first wire, wherein
within the straight-line area, a width of a first preset length of a first wire adjacent to the bonding area is equal to a width of the bonding lead, wherein the first preset length satisfies: a predetermined designed width of the first wire at an end adjacent to the bonding area is larger than a minimum ratio of a width of the second wire to a spacing between two adjacent second wires; or
within the straight-line area, a width of a second preset length of the first wire adjacent to the bonding area is not smaller than a width of the second wire and not larger than a width of each of the plurality of bonding leads, and a width of the second preset length of the first wire at an end near the bonding area is larger than a width of the first wire at an end away from the bonding area, wherein the second preset length satisfies: a predetermined designed width of the first wire at an end adjacent to the bonding area is larger than a minimum ratio of a width of the second wire to a spacing between two adjacent second wires;
a color film substrate; and
a liquid crystal layer between the array substrate and the color film substrate.

11. The display panel of claim 10, wherein the array substrate comprises an organic layer, a protective layer, an insulating layer, a metal wiring layer, and a substrate, the metal wiring layer is disposed on the substrate, the insulating layer is disposed on the metal wiring layer, the protective layer is disposed on the insulating layer, and the organic layer is disposed on the protective layer, the metal wiring layer comprises the bonding leads, the first wires, and the second wires, and the first wire is connected between the bonding lead and the second wire.

12. The display panel of claim 11, wherein the array substrate defines a vias, the array substrate further comprises a conductive film, the metal wiring layer comprises a first wiring part, a second wiring part, and a third wiring part connected in sequence, wherein
the vias penetrates the organic layer, the protective layer, and the insulating layer sequentially to expose the second wiring part of the metal wiring layer, the conductive film covers a sidewall of the vias and the second wiring part of the metal wiring layer at a bottom of the vias, and the conductive film further covers a surface area of the organic layer away from the protective layer; and
the conductive film is electrically connected with the second wiring part of the metal wiring layer in the vias through the bonding lead.

13. The display panel of claim 10, wherein the array substrate comprises an organic layer, a protective layer, a metal wiring layer, an insulating layer, and a substrate, the insulating layer is disposed on the substrate, the metal wiring layer is disposed on the insulating layer, the protective layer is disposed on the metal wiring layer, and the organic layer is disposed on the protective layer, the metal wiring layer comprises the bonding leads, the first wires, and the second wires, and the first wire is connected between the bonding lead and the second wire.

14. The display panel of claim 13, wherein the array substrate defines a vias, the array substrate further comprises a conductive film, the metal wiring layer comprises a first wiring part, a second wiring part, and a third wiring part connected in sequence;
the vias penetrates the organic layer and the protective layer sequentially to expose the second wiring part of the metal wiring layer, the conductive film covers a sidewall of the vias and the second wiring part of the metal wiring layer at a bottom of the vias, and the conductive film further covers a surface area of the organic layer away from the protective layer; and
the conductive film is electrically connected with the second wiring part of the metal wiring layer in the vias through the bonding lead.

15. The display panel of claim 10, wherein the array substrate comprises an organic layer, a protective layer, a second metal wiring layer, an insulating layer, a first metal wiring layer, and a substrate, the first metal wiring layer is disposed on the substrate at a position corresponding to the bonding area, the insulating layer comprises a first insulating part and a second insulating part connected together, the first insulating part is disposed on the first metal wiring layer at a position corresponding to the bonding area, and the second insulating part is disposed on the substrate at a position corresponding to the fanout area; the second metal wiring layer is disposed on the insulating layer, the protective layer is disposed on the second metal wiring layer, and the organic layer is disposed on the protective layer, the first metal wiring layer comprises a part of the bonding leads, and the second metal wiring layer comprises another part of the bonding leads, the first wires, and the second wires.

16. The display panel of claim 15, wherein the array substrate defines a first vias and a second vias, the array substrate comprises a conductive film, the second metal wiring layer comprises a first wiring part, a second wiring part, and a third wiring part connected in sequence;
the first vias penetrates the organic layer, the protective layer, the second metal wiring layer, and the first insulating part of the insulating layer sequentially to expose the first metal wiring layer, and the second vias penetrates the organic layer and the protective layer sequentially to expose the second wiring part of the second metal wiring layer;
the conductive film covers a sidewall of the first vias and the first metal wiring layer at a bottom of the first vias, and a sidewall of the second vias and the second metal wiring layer at a bottom of the second vias, and the conductive film further covers a surface area of the organic layer away from the protective layer and around the first vias and the second vias; and
the conductive film is electrically connected with the first metal wiring layer in the first vias through a bonding lead, and the conductive film is electrically connected with the second wiring part of the second metal wiring layer in the first vias and the second vias through a bonding lead.

17. (canceled)

18. The display panel of claim 10, wherein a width of the second preset length of each of the plurality of first wires is gradually reduced in a direction from near to far relative to the bonding area.
